(19) United States
(12) Patent Application Publication
(10) Pub. No.: US 2002/0181201 A1
(43) Pub. Date: Dec. 5, 2002

(54) Heat dissipating structure of webpad

(75) Inventors: Spring Liu, Taipei (TW); Flanko Lee, Taipei (TW); Mars Lin, Taipei (TW)

Correspondence Address: EDWARDS & ANGELL, LLP, 101 Federal Street, Boston, MA, 02110, US

(73) Assignee: INVENTEC CORPORATION

(21) Appl. No.: 10/047,228

(22) Filed: Jan. 14, 2002

(30) Foreign Application Priority Data
Jun. 1, 2001 (TW) 90209075

(51) Int. Cl. H05K 7/20

(52) U.S. Cl. 361/687; 361/688

(57) ABSTRACT

A heat dissipating structure of a webpad is proposed, in which the webpad is formed with an air inlet, an air outlet, and a guiding tube that passes through a central processing unit and interconnects the air inlet and air outlet, with at least a heat dissipating device provided at a docking station of the webpad. When the webpad is connected to the docking station for high-speed operation, air from the heat dissipating device can pass through the air inlet and guiding tube to the central processing unit, and air taken with heat of the central processing unit is outputted through the air outlet to the atmosphere for effectively dissipating the heat generated by the central processing unit, so as to prevent the central processing unit from being damaged by overheat.

### FIELD OF INVENTION

The present invention relates to heat dissipating structures of webpads, and more particularly, to a heat dissipating structure of a webpad in which a heat dissipating device such as a fan is incorporated with a docking station of the webpad, so as to effectively dissipate heat generated by a central processing unit of the webpad, without altering the dimensions of the webpad in the provision of the heat dissipating structure.

### BACKGROUND OF THE INVENTION

Among various information appliances, besides PDA (personal digital assistant), webpads dimensionally similar to magazines are drawn much public attention thereto.

A webpad is dedicated equipment specifically designed for accessing a network, that is, its primary function is to provide network access. The webpad is advantageous of its portability and easiness in use, allowing a user to wirelessly login the network and send and receive e-mails at any place and time, with no need of using a desktop computer.

The webpad is mainly composed of a touch-control liquid crystal display (LCD) panel with a light and thin mainframe attached to back of the panel, in no provision of a floppy disk or hard disk. Similar to a personal computer (PC), the webpad also has a central processing unit (CPU) and operating system (OS). The webpad is touch-controllably operated as a pocket PC by using a pen, and provided with USB ports, instead of complicated I/O interfaces, to be connected to peripheral equipment such as a keyboard, printer and so on.

Therefore, the webpad is becoming a consumer electronic product for desirably providing network access, which is accomplished simply by pressing a power button to initiate the webpad and accessing a network immediately, without spending time for a computer log-on process and a complex network dial-up procedure. It is particularly advantageous for computer learners, who only need to use a pen instead of a mouse for browsing the network and retrieving required information, and thus do not need to have advanced knowledge of computer manipulation.

Compared to the pocket PC, the webpad has a relatively larger LCD panel, thereby providing more convenience for a user to browse a web page.

The webpad is accessorized with a docking station that is used as an external interface to be connected to a keyboard for allowing a user to work in the office or at home, or to a charger for power recharging. Moreover, USB ports of the docking station can be externally connected to peripheral equipment such as a disk drive, CD-ROM drive or hard disk, so as to broaden the functions of the webpad.

However, in purpose of portability and easiness in operation, the webpad is necessarily miniaturized in profile, thereby making the webpad unable to be incorporated at its CPU with a heat dissipating device such as a fan, unlike a conventional PC with facility of heat dissipation.

Thus, under a condition in no combination with a docking station, the CPU of the webpad is designed to retrieve power only from batteries, and to automatically reduce its frequency for merely processing basic operations such as network accessing by using lower voltage for producing less heat, so as to protect the CPU from being damaged by overheat in no provision of a heat dissipating device. When the webpad is electrically connected to the docking station, the CPU thereof can automatically recover to operate at full speed for proceeding complicated processes and manipulations. However, this accordingly results in a larger amount of heat produced by the CPU. If the heat can not be effectively dissipated, it may adversely affect the functionality and even severely damage the CPU of the webpad.

### SUMMARY OF THE INVENTION

Therefore, in order to solve the foregoing drawbacks, a primary objective of the present invention is to provide a heat dissipating structure of a webpad, in which a heat dissipating device such as a fan is incorporated with a docking station of the webpad, so as to effectively dissipate heat produced by a central processing unit (CPU) of the webpad during complicated operations or manipulations, and to prevent the CPU from being damaged by overheat.

In accordance with the above and other objectives, the present invention proposes a heat dissipating structure of a webpad, comprising: an air inlet and an air outlet formed at the webpad, wherein the air inlet extends through inside of the webpad and a CPU to form a guiding tube that passes a CPU of the webpad and interconnects the air inlet and the air outlet; a connecting portion formed at a docking station and detachably coupled to the air inlet of the webpad; and at least a heat dissipating fan mounted underneath the connecting portion. When the webpad is connected to the docking station, air provided from the heat dissipating fan is transferred through the air inlet and guiding tube to the CPU of the webpad, for reducing the temperature of the CPU. Then, air taken with heat of the CPU is outputted through the air outlet, so that the heat generated by the CPU can be dissipated.

### BRIEF DESCRIPTION OF THE DRAWINGS

The present invention can be better understood by reading the following detailed description of the preferred embodiments, with reference made to the accompanying drawings, wherein:

FIG. 1 is a cross-sectional view of a webpad and a docking station for use with a preferred embodiment of the invention;

FIG. 2 is a schematic diagram illustrating the heat dissipation status through the connection between a webpad and a docking station of FIG. 1;

FIG. 3 is a cross-sectional view of another preferred embodiment of the invention; and

FIG. 4 is a schematic diagram illustrating the heat dissipation status through the connection between a webpad and a docking station of FIG. 3.

### DETAILED DESCRIPTION OF THE PREFERRED EMBODIMENTS

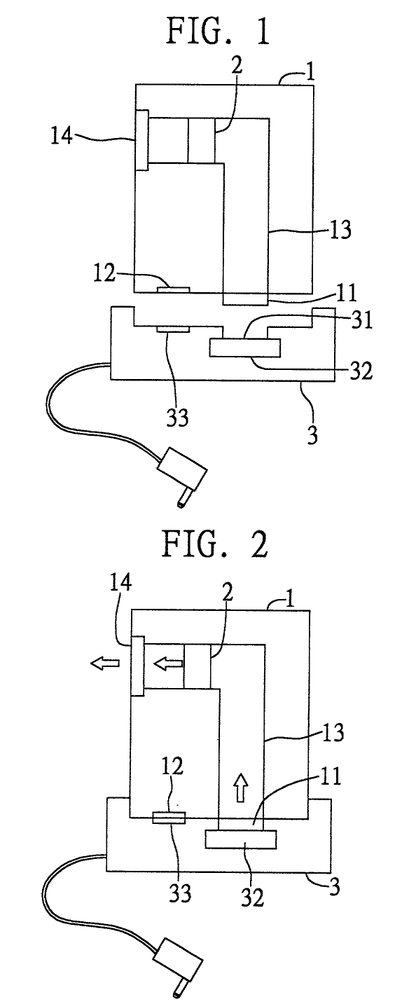

Referring to FIG. 1, a heat dissipating structure of a webpad 1 of the present invention is accomplished as follows. The webpad 1 is formed at a side thereof with an air inlet 11 and a connector 12, whereas at another side of the webpad 1 there is provided an air outlet 14. The air inlet 11 extends through inside of the webpad 1 to form a guiding tube 13 that passes a central processing unit (CPU) 2 and interconnects the air inlet 11 and the air outlet 14. The CPU 2 is designed with a function of automatic frequency modulation; that is, it can self-adjust its processing mode to be in high-speed or low-speed operation depending on whether the webpad 1 is connected to a docking station 3 or not. Moreover, the docking station 3 is provided with a connecting portion 31 detachably coupled to the air inlet 11 of the webpad 1, and at least a heat dissipating device 32 such as a fan mounted underneath the connecting portion 31 that is formed with an opening for exposing the heat dissipating device 32. When the webpad 1 utilizes batteries as a power source, the CPU 2 can automatically determine that the webpads 1 is not connected to the docking station 3, and reduce its frequency to operate in the low-speed mode that only allows basic manipulations, so as to relatively decrease heat production.

Referring to FIG. 2, after the webpad 1 is combined with the docking station 3, the connector 12 positioned at bottom of the webpad 1 comes into contact with a connector 33 of the docking station 3, allowing power supply to be switched to an alternating current mode. In the meantime, the CPU 2 automatically determines that the webpad 1 is connected to the docking station 3, and switches to a high-level operating mode that allows more complicated manipulations to be proceeded by the CPU 2 at full speed operation, thereby resulting in significantly increased amount of heat produced by the CPU 2. As such, air provided from the heat dissipating device 32 can pass through the air inlet 11 and guiding tube 13 to the CPU 2, and air taken with heat of the CPU 2 is outputted through the air outlet 14 so as to effectively dissipate the heat generated by the CPU 2.

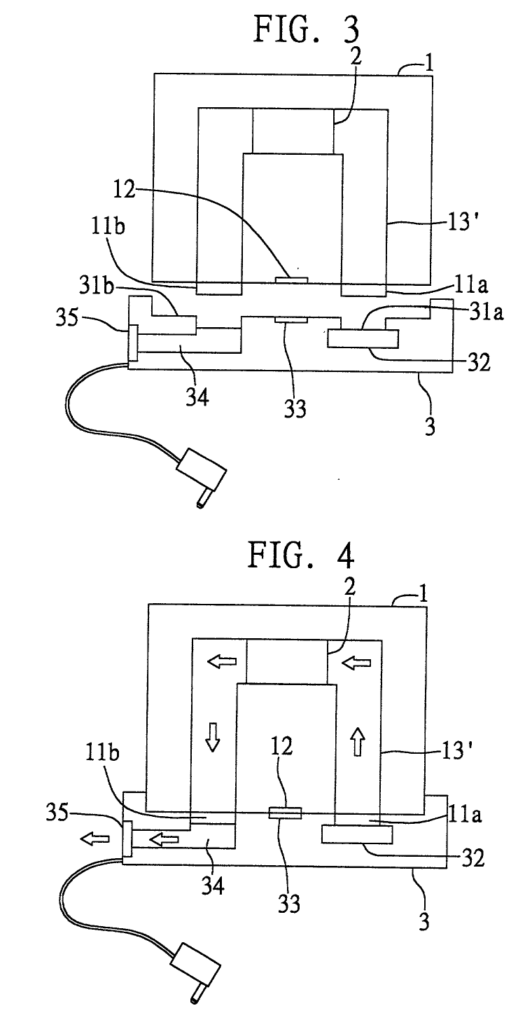

FIG. 3 illustrates another preferred embodiment of the invention. This embodiment is structurally similar to the foregoing embodiment. The difference is that, after passing through the CPU 2, a guiding tube 13′ of the webpad 1 can further extend towards a side of the webpad 1 where an air inlet 1 la is located, so as to form an air outlet 11b aside the air inlet 11a. And, the docking station 3 is provided with an inlet connecting portion 31a and an outlet connecting portion 31b detachably coupled to the air inlet 11a and the air outlet 11b, respectively. Further, a guiding tube 34 is formed within the docking station 3, with one end of the guiding tube 34 being connected to the outlet connecting portion 31b, and the other end thereof being communicated with an air outlet 35 formed at a side of the docking station 3.

Referring to FIG. 4, after the webpad 1 is associated with the docking station 3, air provided from the heat dissipating device 32 can pass through the air inlet 11a, guiding tube 13′ to the CPU 2, and air taken with heat of the CPU 2 is transferred through the air outlet 11b to the guiding tube 34 of the docking station 3 and then through the air outlet 35 of the docking station 3 to the atmosphere; this can therefore effectively dissipate the heat generated by the CPU 2 under high-speed operation.

In addition, the heat dissipating device 32 can be operated under manual or automatic control; that is, the heat dissipating device 32 can automatically start to operate when the connector 12 of the webpad 1 comes into contact with the connector 33 of the docking station 3. Moreover, the heat dissipating device 32 can be mounted with a sensor, allowing the heat dissipating device 32 to be initiated for operation when the sensor senses that heat or temperature produced by the CPU 2 reaches a predetermined value, so that the CPU 2 can be prevented from being damaged by overheat.

It is understood that, the foregoing heat dissipating device 32 and guiding tubes 13, 13′ can be alternatively replaced by other conventional heat dissipating means such as heat sink, heat pipe, etc. This still substantially achieves the same improvements as rendered by the invention.

In conclusion of the above description, the heat dissipating structure of the invention is advantageous of effectively dissipating the heat generated by the CPU of the webpad under high-speed operation, so as to assure the functionality and lifetime of the CPU. Moreover, the provision of this heat dissipating structure is not involved in altering the dimensions of the webpad, thereby without causing any inconvenience in usage.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A heat dissipating structure of a webpad, comprising:
an air inlet and an air outlet formed at the webpad, wherein the air inlet extends through inside of the webpad to form a guiding tube that passes a central processing unit of the webpad and interconnects the air inlet and the air outlet;
an inlet connecting portion formed at a docking station of the webpad and detachably coupled to the air inlet of the webpad; and
at least a heat dissipating device mounted underneath the connecting portion;
wherein air provided from the heat dissipating device passes through the air inlet and the guiding tube to the central processing unit, and air taken with heat of the central processing unit is outputted through the air outlet for dissipating the heat generated by the central processing unit.

2. The heat dissipating structure of claim 1, wherein the docking station is further provided with an outlet connecting portion, that is detachably coupled to the air outlet of the webpad and connected to a guiding tube formed within the docking station, whereas the guiding tube of the docking station is associated with an air outlet formed at a side of the docking station.

3. The heat dissipating structure of claim 1, wherein the webpad uses batteries as a power source.

4. The heat dissipating structure of claim 1, wherein the webpad uses alternating currents as a power source.

5. The heat dissipating structure of claim 1, wherein the central processing unit automatically determines if the webpad is connected to the docking station so as to adjust an operating mode of the central processing unit.

6. The heat dissipating structure of claim 5, wherein the central processing unit automatically switches to a low-speed operating mode if the webpad uses batteries as a power source, so as to reduce heat production in operation.

7. The heat dissipating structure of claim 5, wherein the central processing unit automatically switches to a high-speed operating mode if the webpad uses alternating currents as a power source, allowing the central processing unit to operate at full speed.

8. The heat dissipating structure of claim 1, wherein the heat dissipating device is operated by manual control.

9. The heat dissipating structure of claim 1, wherein the heat dissipating device is operated by automatic control, and is initiated for operation if a connector formed at bottom of the webpad comes into contact with a connector of the docking station.

10. The heat dissipating structure of claim 1, wherein the webpad is provided with a sensor, and the heat dissipating device is initiated for operation if the sensor senses that heat or temperature produced by the central processing unit reaches a predetermined value, so as to prevent the central processing unit from being damaged by overheat.

11. The heat dissipating structure of claim 2, wherein the webpad uses batteries as a power source.

12. The heat dissipating structure of claim 2, wherein the webpad uses alternating currents as a power source.

13. The heat dissipating structure of claim 2, wherein the central processing unit automatically determines if the webpad is connected to the docking station so as to adjust an operating mode of the central processing unit.

14. The heat dissipating structure of claim 13, wherein the central processing unit automatically switches to a low-speed operating mode if the webpad uses batteries as a power source, so as to reduce heat production in operation.

15. The heat dissipating structure of claim 13, wherein the central processing unit automatically switches to a high-speed operating mode if the webpad uses alternating currents as a power source, allowing the central processing unit to operate at full speed.

16. The heat dissipating structure of claim 2, wherein the heat dissipating device is operated by manual control.

17. The heat dissipating structure of claim 2, wherein the heat dissipating device is operated by automatic control, and is initiated for operation if a connector formed at bottom of the webpad comes into contact with a connector of the docking station.

18. The heat dissipating structure of claim 2, wherein the webpad is provided with a sensor, and the heat dissipating device is initiated for operation if the sensor senses that heat or temperature produced by the central processing unit reaches a predetermined value, so as to prevent the central processing unit from being damaged by overheat.
